(19) United States
(12) Patent Application Publication
(10) Pub. No.: US 2015/0255614 A1
(43) Pub. Date: Sep. 10, 2015

(54) SPLIT GATE FLASH MEMORY AND MANUFACTURING METHOD THEREOF

(71) Applicant: Powerchip Technology Corporation, Hsinchu (TW)

(72) Inventors: Yukihiro Nagai, Hsinchu City (TW); Ikuo Kurachi, Hsinchu City (TW)

(73) Assignee: Powerchip Technology Corporation, Hsinchu (TW)

(21) Appl. No.: 14/197,234

(22) Filed: Mar. 5, 2014

(51) Int. Cl. H01L 29/788; H01L 29/423; H01L 29/66

(52) U.S. Cl. CPC H01L 29/7889; H01L 29/66825; H01L 29/4236

(57) ABSTRACT

A split gate flash memory is provided. A device isolation structure is disposed in a substrate to define an active area. A first doping region and a second doping region are respectively disposed in an active area of the substrate. A select gate is disposed in a trench in the substrate, and a side of the select gate is adjacent to the first doping region. A gate dielectric layer is disposed between the select gate and the substrate. A floating gate is disposed on the substrate, a side of the floating gate overlaps to the second doping region, and a portion of the floating gate is disposed on the select gate. An inter-gate dielectric layer is disposed between the floating gate and the select gate and between the floating gate and the substrate.

### BACKGROUND OF THE INVENTION

1. Field of the Invention

The present invention relates to a semiconductor device. More particularly, the present invention relates to a split gate flash memory and manufacturing method thereof.

2. Description of Related Art

Due to the fact that data can be stored, read out, erased, etc. many times and stored data are retained even after power supplying is cut off, a flash memory device is a non-volatile memory device that has been widely used inside personal computers and electronic equipments.

Typically, the floating gate and the control gate of the flash memory device are fabricated using doped polysilicon. Furthermore, the floating gate and the control gate are isolated from each other through a dielectric layer and the floating gate and a substrate are isolated from each other through a tunneling oxide layer. To perform a data write/erase operation on the flash memory, a biased voltage is applied to the control gate and source/drain regions, so that electrons are injected into the floating gate or pulled out from the floating gate. To read data from the flash memory, an operating voltage is applied to the control gate so that the charging state of the floating gate will turn ‘on’ or ‘off’ the channel underneath. Consequently, the ‘on’ or ‘off’ state of the channel can be used to determine if a ‘0’ or ‘1’ data bit is read out.

Because the quantity of electrons expelled from the floating gate when erasing data from the aforementioned flash memory is difficult to control, too many charges may be easily expelled from the floating gate which leads to the floating gate having net positive charges, the so-called ‘over-erase’. If the degree of the over-erasing phenomenon is severe, the channel underneath the floating gate may continue to be conductive even though no operating voltage is applied to the control gate. As a result, errors in reading out the data may occur.

To resolve the over-erasing problem of the device, a split gate flash memory has been proposed by the industry currently. The split gate flash memory has a structure comprising a tunnelling dielectric layer, a floating gate, an inter-gate dielectric layer, and a select gate sequentially formed over a substrate. Aside from located on the floating gate, a portion of the select gate also extends to cover an area above the substrate. The select gate is isolated from the substrate through a select gate dielectric layer. The source region is located in the substrate on one side of the floating gate. The drain region is located in the substrate on the same side as the extension of the select gate. With this setup, even when the over-erasing problem is so severe that the channel underneath the floating gate remains turned on in the absence of an operating voltage to the select gate, the channel underneath the select gate is still maintained in the turned-off state. Thus, the drain region and the source region are cut off from each other and the errors in reading out the data are prevented.

However, the split gate structure needs a larger area to accommodate the split gate so that the size of each memory cell is increased. Thus, the memory cell with the split gate structure must occupy a larger area compared with the memory cell with a stack gate structure, so that level of integration of the devices can hardly be increased.

Furthermore, as the level of integration of integrated circuits continues to increase so as to develop toward miniaturization of the device, the size of each memory cell can be reduced by shortening gate length of the memory cell. Yet, a shorter gate will lead to a reduction of the channel length underneath the gate. With a shorter channel, the chance of having an abnormal punch through between the drain region and the source region is increased during memory cell programming. Ultimately, the electrical performance of the memory cell will be seriously affected.

### SUMMARY OF THE INVENTION

The invention is to provide a split gate flash memory, by which the level of integration of the devices can be increased, the interference during programming can be reduced, and the operation speed of the memory device can be improved.

The invention is to provide a manufacturing method of the split gate flash memory cell, wherein a floating gate can be manufactured in the same process step with a gate of a transistor in a peripheral circuit area, and thus the manufacturing of the floating gate can be integrated with existing processes.

A split gate flash memory of the invention includes a device isolation structure, a first doping region and a second doping region, a select gate, a gate dielectric layer, a floating gate, and an inter gate dielectric layer. The device isolation structure is disposed in a substrate to define an active area. The first doping region and the second doping region are respectively disposed in the active area of the substrate. The select gate is disposed in a trench of the substrate, and a side of the select gate is adjacent to the first doping region. The gate dielectric layer is disposed between the select gate and the substrate. The floating gate is disposed on the substrate, wherein a side of the floating gate overlaps to the second doping region, and a portion of the floating gate is disposed on the select gate. The inter gate dielectric layer is disposed between the floating gate and the select gate and between the floating gate and the substrate.

In an embodiment of the invention, a surface of the device isolation structure in the trench is lower than a surface of the substrate, and a portion of the select gate is saddle-shaped and is across the active area.

In an embodiment of the invention, the active area between the device isolation structures in the trench forms a notch, and a portion of the select gate is fin-shaped and extrudes the active area.

In an embodiment of the invention, a portion of the floating gate extrudes the select gate and a corner where the floating gate extrudes the select gate has a sharp shape.

In an embodiment of the invention, a material of the select gate includes metal or doped polysilicon.

In an embodiment of the invention, a material of the floating gate includes doped polysilicon.

A manufacturing method of the split gate flash memory of the invention includes following steps: forming a device isolation structure in a substrate to define an active area; forming a patterned mask layer on the substrate; removing a portion of the device isolation structure and the substrate using the patterned mask layer as a mask to form a trench in the substrate; forming a gate dielectric layer in the trench; forming a select gate to fill the trench; removing the patterned mask layer; forming an inter gate dielectric layer on the substrate; forming a floating gate on the substrate, wherein a portion of the floating gate is disposed on the select gate; and forming a first doping region and a second doping region in the substrate on both sides of the floating gate and the select gate, wherein the first doping region is adjacent to a side of the select gate and the second doping region overlaps to a side of the floating gate.

In an embodiment of the invention, the step of removing the portion of the device isolation structure and the substrate using the patterned mask layer as the mask to form the trench in the substrate includes removing the portion of the device isolation structure to form the notch in the device isolation structure.

In an embodiment of the invention, the above-mentioned step of removing the portion of the device isolation structure and the substrate using the patterned mask layer as the mask to form the trench in the substrate includes removing the portion of the substrate to form the notch between the device isolation structures.

In an embodiment of the invention, the step of forming the select gate in the trench of which the select gate fills the trench includes forming a conductive material layer on the substrate, wherein the conductive material layer fills the trench; and removing a portion of the conductive material layer to form a recess surface on the conductive material layer.

In an embodiment of the invention, the step of forming the inter gate dielectric layer on the substrate includes performing thermal oxidation.

In an embodiment of the invention, the step of forming the floating gate on the substrate includes forming the conductive material layer on the substrate; and patterning the conductive material layer.

According to the above, in the split gate flash memory and the manufacturing method thereof of the invention, the size of the device can be reduced by disposing the select gate in the trench in the substrate. Also, the channel length of the select gate can be controlled by the depth of the trench.

In the split gate flash memory and the manufacturing method thereof of the invention, since the floating gate extrudes the select gate and the sharp corner is formed, a higher electric field can be produced at the corner. Accordingly, when the data erase operation is performed on the flash memory, time required for the data erase operation can be shortened, and a voltage applied to the select gate can also be reduced.

In the split gate flash memory and the manufacturing method thereof of the invention, the select gate is disposed in a trench of the substrate for cell shrinkage. Further, in the split gate flash memory and the manufacturing method thereof of the invention, since a portion of the select gate is saddle-shaped and is across the active area or a portion of the select gate is slightly fin-shaped and extrudes the active area, the memory cell has a three dimensional channel path, which increases the channel width. According to the fact that the channel width underneath the select gate is increased, the size of the memory cell can be reduced, thereby increasing the level of integration of the device. Furthermore, the channel width underneath the select gate can be determined by the depth of the removed device isolation structure or the depth of the notch of the active area.

In order to make the aforementioned and other features and advantages of the invention comprehensible, embodiments accompanied with figures are described in detail below.

### BRIEF DESCRIPTION OF THE DRAWINGS

FIG. 1A is a top view illustrating a split gate flash memory according to an embodiment of the invention.

FIG. 1B is a cross-sectional view illustrating the split gate flash memory according to an embodiment of the invention along a line A-A′ of FIG. 1A.

FIG. 1C is a cross-sectional view illustrating the split gate flash memory according to an embodiment of the invention along a line B-B′ of FIG. 1A.

FIG. 1D is a cross-sectional view illustrating the split gate flash memory according to another embodiment of the invention along a line B-B′ of FIG. 1A.

FIG. 1E is a cross-sectional view illustrating a split gate flash memory according to another embodiment of the invention along the line B-B′ of FIG. 1A.

FIG. 2A is a schematic view illustrating a programming operation mode of a split gate flash memory according to an embodiment of the invention.

FIG. 2B is a schematic view illustrating an erasing operation mode of a split gate flash memory according to an embodiment of the invention.

FIG. 3A to FIG. 3E are cross-sectional views illustrating a manufacturing process of a split gate flash memory according to an embodiment of the invention.

### DESCRIPTION OF EMBODIMENTS

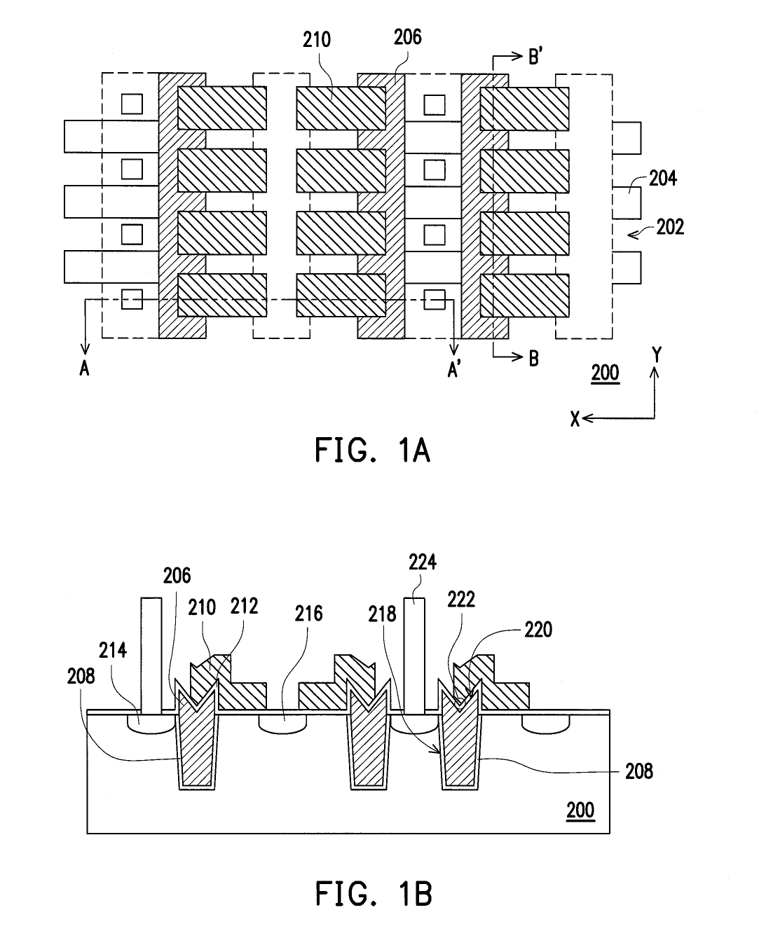

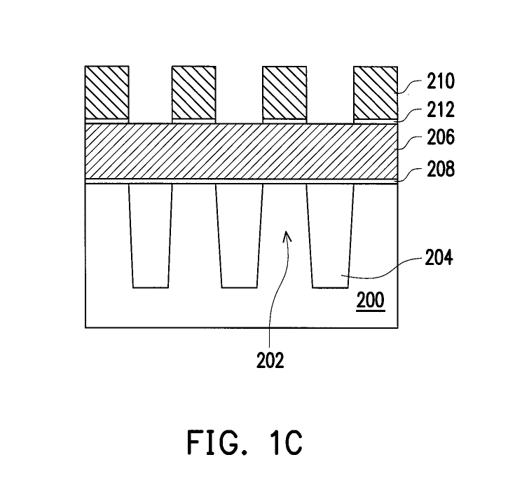

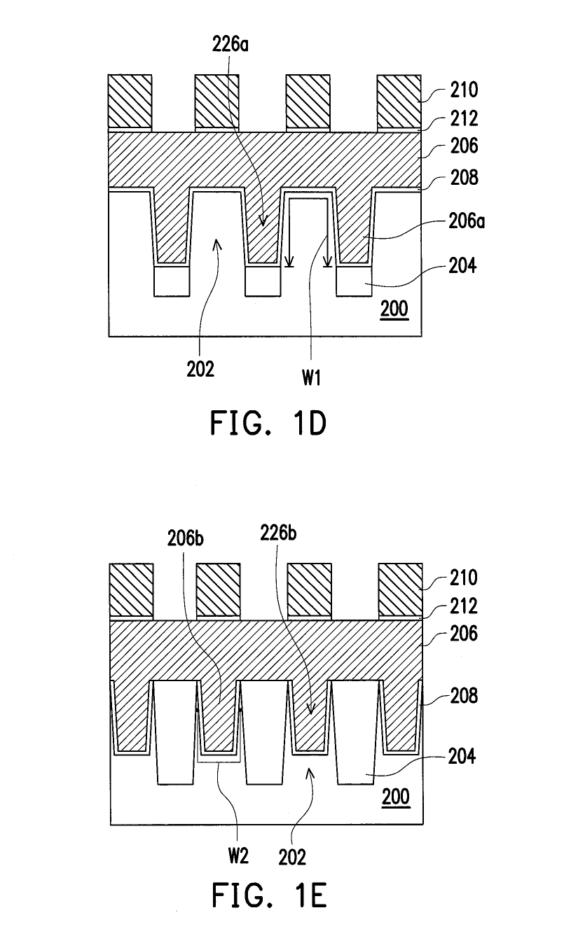

FIG. 1A is a top view illustrating a split gate flash memory according to an embodiment of the invention. FIG. 1B is a cross-sectional view illustrating the split gate flash memory according to an embodiment of the invention along a line A-A′ of FIG. 1A. FIG. 1C is a cross-sectional view illustrating the split gate flash memory according to an embodiment of the invention along a line B-B′ of FIG. 1A. FIG. 1D is a cross-sectional view illustrating a split gate flash memory according to another embodiment of the invention along the line B-B′ of FIG. 1A.

First, to illustrate a split gate flash memory of the invention, please refer to FIG. 1A to FIG. 1E. The split gate flash memory of the invention includes a substrate 200, an active area 202, a device isolation structure 204, a select gate 206, a gate dielectric layer 208, a floating gate 210, an inter gate dielectric layer 212, a doping region 214 (a drain region), and a doping region 216 (a source region).

The substrate 200 is, for instance, a silicon substrate. The device isolation structures 204 are disposed in the substrate 200 to define the active area 202. The device isolation structures 204, for instance, are arranged in parallel in the X direction and extend in the X direction to appear to be strip-shaped. The device isolation structures 204 are, for instance, shallow trench isolation structures. Material of the device isolation structures 204 is, for instance, silicon oxide.

The doping region 214 (the drain region) and the doping region 216 (the source region) are, for instance, respectively disposed in the active area 202 of the substrate 200, wherein the doping region 214 (the drain region) and the doping region 216 (the source region) are separated by the select gate 206 and the floating gate 210 and are opposed to each other.

The select gate 206 is, for instance, disposed in a trench 218 of the substrate 200, and a side of the select gate 206 is adjacent to the doping region 216. The select gates 206, for instance, are arranged in parallel in the Y direction and extend in the Y direction to appear to be strip-shaped. Material of the select gate 206 includes conductive material, such as metal, doped polysilicon and so on. The select gate 206 may have a single-layered structure formed by a metal layer, or a multi-layered structure formed by metal nitride layers (barrier layers) and metal layers. Metal may be such as aluminum, tungsten, titanium, copper, or combinations thereof. Metal nitride may be TiN, TaN, or combinations thereof.

The gate dielectric layer 208 is, for instance, disposed between the select gate 206 and the substrate 200. Material of the gate dielectric layer 208 is, for instance, silicon oxide.

The floating gate 210 is disposed on the substrate 200, a side of the floating gate 210 overlaps to the doping region 216 (the source region), and a portion of the floating gate 210 is disposed on the select gate 206. Material of the floating gate 210 is, for instance, doped polysilicon.

The inter gate dielectric layer 212 is, for instance, disposed between the floating gate 210 and the select gate 206 and between the floating gate 210 and the substrate 200. Material of the inter gate dielectric layer 212 is, for instance, silicon oxide. In addition, a plug 224 for connecting to bit lines (not shown) may also be disposed on the doping region 214 (the drain region).

Please refer to FIG. 1B. The select gate 206 of the invention extrudes the surface of the substrate 200, and a top of the select gate 206 has a recession 220. It is due to the recession 220 that a portion of the floating gate 210 extrudes the select gate 206 and a corner 222 where the floating gate 210 extrudes the select gate 206 has a sharp shape. Since the corner 222 where the formed floating gate 210 extrudes the select gate 206 has a sharp shape, the higher electric field can be produced at the corner 222 where the floating gate 210 extrudes the select gate 206. Accordingly, when the data erase operation is performed on the flash memory, the time required for the erase operation can be shortened, and the voltage applied to the select gate 206 can also be reduced.

Please refer to FIG. 1C. In an embodiment, since the select gate 206 is disposed in a trench 218 of the substrate 200, the channel region of the select gate 206 is configured in the substrate 200 along the sidewall of the trench (vertical channel region). Therefore, even the device dimension (gate length) is reduced, the channel length is accurately controlled by controlling the depth of the trench. The problem of a leakage between the source region and the drain region after programming is prevented. Further, the integration of device can also increase.

Please refer to FIG. 1D. In another embodiment, since a surface of the device isolation structure 204 in the trench 218 is lower than a surface of the substrate 200 (that is, a notch 226a is formed in the device isolation structure 204), a portion 206a of the select gate 206 is saddle-shaped and is across the active area 202. Accordingly, the memory cell has the three dimensional channel path, which increases the channel width W1. Please refer to FIG. 1E. In another embodiment, since a notch 226b is formed in the active area 202 between the device isolation structures 204 in the trench 218, a portion 206b of the select gate 206 is slightly fin-shaped and extrudes the active area 202. Accordingly, the memory cell has the three dimensional channel path, which increases the channel width W2.

A plurality of memory cells are formed on the substrate 200. The memory cells are, for instance, arranged in an array. Two adjacent memory cells have, for instance, the same and symmetrical structures, and the two adjacent memory cells share one doping region 214 (the drain region) or one doping region 216 (the source region).

In the split gate flash memory of the invention, since the select gate 206 is disposed in the trench 218 in the substrate 200, the size of the device can be reduced. Also, the channel length of the select gate 206 can be controlled by the depth of the trench.

In the split gate flash memory of the invention, since the floating gate 210 extrudes the select gate 206 and the corner 222 is formed (as shown in FIG. 1B), the higher electric field can be produced at the corner 222. Accordingly, when the data erase operation is performed on the flash memory, the time required for the erase operation can be shortened, and the voltage applied to the select gate 206 can also be reduced.

In the split gate flash memory of the invention, the portion 206a of the select gate 206 is saddle-shaped and is across the active area 202 or the portion 206b of the select gate 206 is slightly fin-shaped and extrudes the active area 202. Accordingly, the memory cell has the three dimensional channel path, which increases the channel width. Due to the fact that the channel width underneath the select gate 206 is increased, the size of the memory cell can be reduced, thereby increasing the level of integration of the device. In addition, the channel width underneath the select gate 206 can be determined by the depth of the removed device isolation structure or the depth of the notch of the active area.

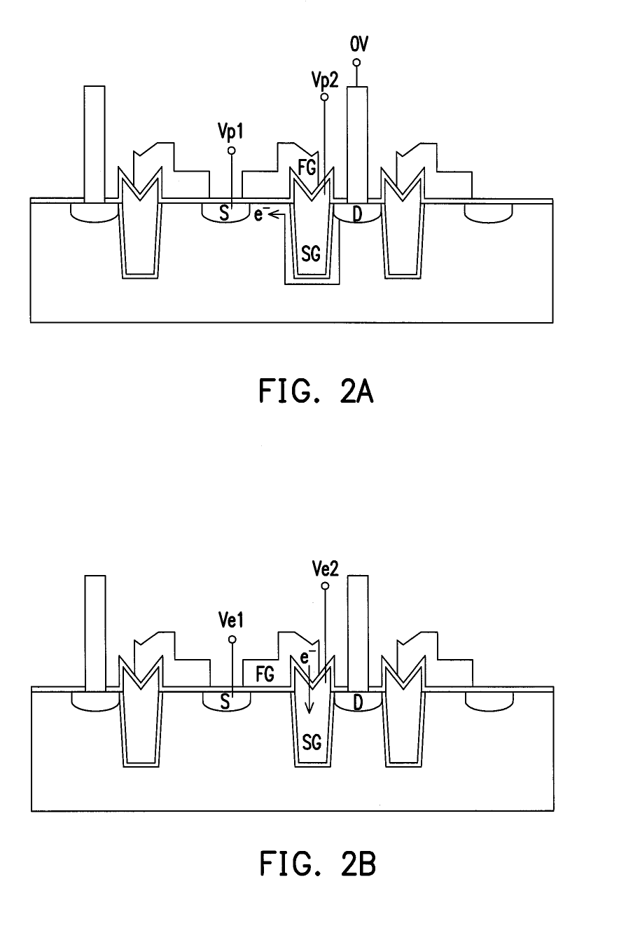

Next, to understand operation modes of the split gate flash memory in the preferred embodiment of the invention, please refer to FIG. 2A and FIG. 2B. The operation modes include a programming operation mode (FIG. 2A), an erasing operation mode (FIG. 2B), and the like.

When the programming operation is performed on the memory cell, a voltage Vp1 is applied to the source region S, a voltage Vp2 is applied to the select gate SG to turn on the channel underneath the select gate SG, and the drain region D has a voltage of around 0 volt. For example, the voltage Vp1 is about 2 volts and the voltage Vp2 is about 8 volts. Accordingly, electrons are moved from the drain region D to the source region S, and the electrons are accelerated in the source region S by the high electric field of the channel, whereby hot electrons are produced. The kinetic energy of the hot electrons is high enough to overcome the energy barrier of the inter gate dielectric layer (the inter gate dielectric layer between the floating gate and the substrate is as a tunneling dielectric layer), so that the hot electrons are injected into the floating gate FG from the source region S.

When the erasing operation is performed on the memory cell, a voltage Ve1 is applied to the source region S, a voltage Ve2 is applied to the select gate SG, and the drain region D is floating. For instance, the voltage Ve1 is about −2 volts and the voltage Ve2 is about 12 volts. Accordingly, the large electric field can be created between the floating gate FG and the select gate SG, so that an F-N tunneling effect can be used to pull the electrons out from the floating gate FG to the select gate SG.

In the above-mentioned embodiments, the higher electric field can be produced at the corner where the floating gate FG extrudes the select gate SG when the erasing operation is performed in the invention. Accordingly, when the data erase operation is performed on the flash memory, the time required for the erase operation can be shortened, and the voltage applied to the select gate SG can also be reduced.

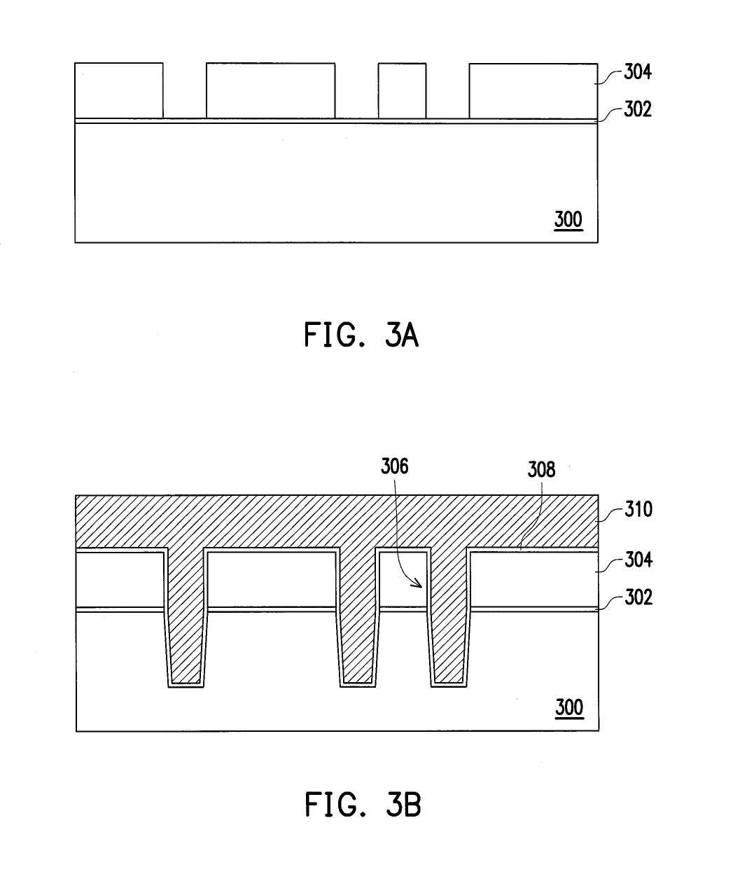

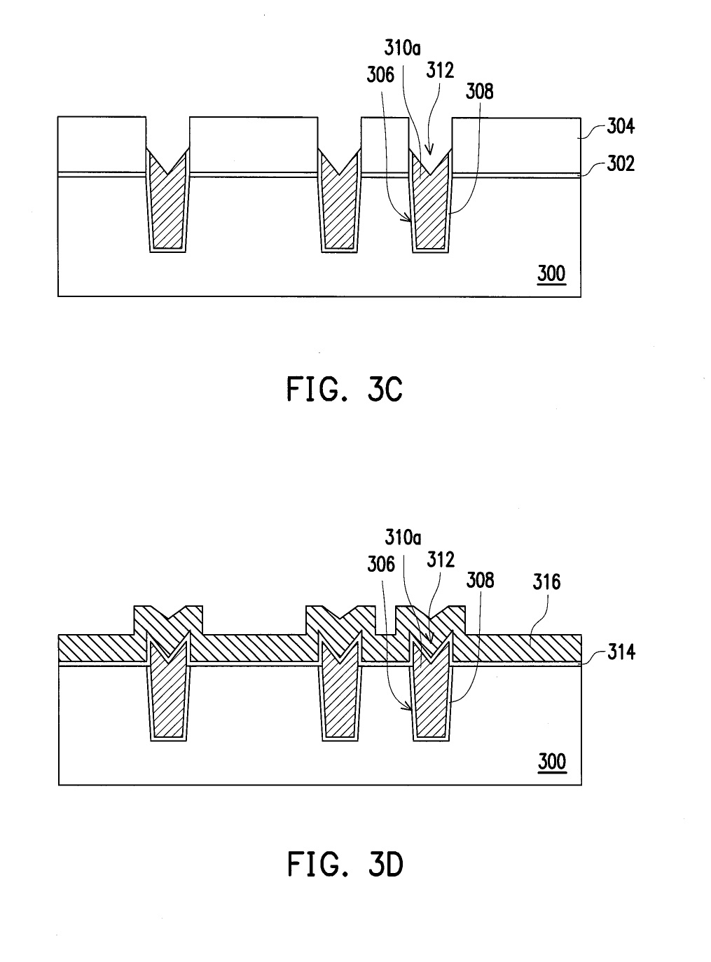

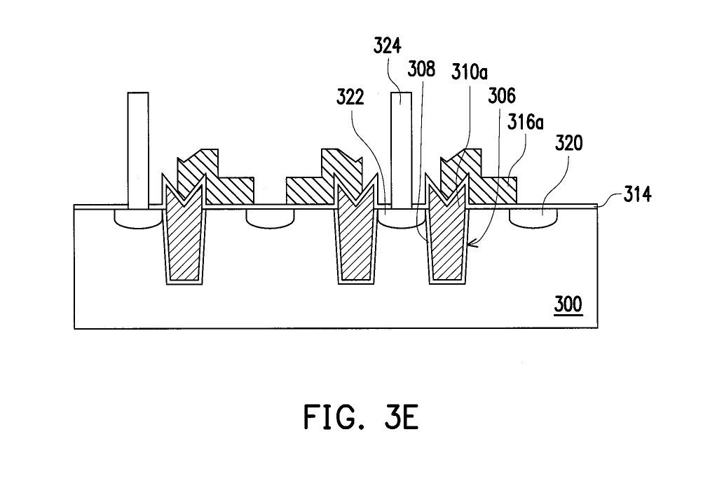

FIG. 3A to FIG. 3E are views illustrating a manufacturing process of a split gate flash memory according to a preferred embodiment of the invention. FIG. 3A to FIG. 3E are for illustrating the manufacturing method of the flash memory of the invention.

First, please refer to FIG. 3A. A substrate 300 is provided. The substrate 300 is, for instance, a silicon substrate. A device isolation structure (not shown) is such as already formed in the substrate 300. The device isolation structures, for instance, are arranged in parallel in the X direction and extend in the X direction to appear to be strip-shaped (as shown in FIG. 1A). A liner layer (pad oxide) 302 and a mask layer 304 are formed sequentially on the substrate 300. Material of the liner layer 302 is such as silicon oxide. A method of forming the liner layer 302 is, for instance, a thermal oxidation. Material of the mask layer 304 is such as silicon nitride. A method of forming the mask layer 304 is, for instance, a chemical vapor deposition. Next, the mask layer 304 is patterned. A method of patterning the mask layer 304 is, for instance, a lithography-etching technique.

Please refer to FIG. 3B. Portions of the liner layer 302, the device isolation structure, and the substrate 300 are removed by using the patterned mask layer 304 as a mask so as to form trenches 306 in the substrate 300. The trenches 306, for instance, are arranged in parallel in the Y direction and extend in the Y direction to appear to be strip-shaped (as shown in FIG. 1A). A method of removing portions of the liner layer 302 and the substrate 300 is such as a reactive ion etching. In the above-mentioned step, since the trenches 306 is formed in the substrate 300, the channel region of a select gate formed in a subsequent step is configured in the substrate 300 along the sidewall of the trench (vertical channel region). Therefore, even the device dimension is reduced, the channel length is accurately controlled by controlling the depth of the trench. The problem of a leakage between the source region and the drain region after programming is prevented. Further, the integration of device can also increase (as shown in FIG. 1C).

In the above-mentioned step, notches are further formed in the device isolation structures by making a surface of the device isolation structure in the trenches 306 lower than a surface of the substrate 300 when removing portions of the device isolation structure; or, the notches are further formed in the substrate 300 between the device isolation structures by making the surface of the substrate 300 in the trenches 306 lower than the surface of the device isolation structure when removing portions of the substrate 300. By adjusting the etching recipe in the process of forming the trenches 306, the etching rate of the device isolation structure (silicon oxide) may be larger than the etching rate of the substrate (silicon), so that the surface of the device isolation structure in the trenches 306 may be lower than the surface of the substrate (as shown in FIG. 1D). Similarly, by adjusting the etching recipe in the process of forming the trenches 306, the etching rate of the device isolation structure (silicon oxide) may also be less than the etching rate of the substrate (silicon), so that the notches may be formed in the substrate between the device isolation structures (as shown in FIG. 1E).

Then, a gate dielectric layer 308 is formed on the substrate 300. Material of the gate dielectric layer 308 is, for instance, silicon oxide. Methods of forming the gate dielectric layer 308 are, for instance, the thermal oxidation, the chemical vapor deposition, or an atomic layer deposition, etc. Next, a conductive material layer 310 is formed on the substrate 300 to fill the trenches 306. Material of the conductive material layer 310 is such as metal, etc. The conductive material layer 310 may have a single-layered structure formed by a metal layer, or a multi-layered structure formed by metal nitride layers (barrier layers) and metal layers. Metal may be such as aluminum, tungsten, titanium, copper, or combinations thereof. Metal nitride may be TiN, TaN, or combinations thereof. A method of forming the conductive material layer 310 is, for instance, performing the chemical vapor deposition to sequentially form the metal nitride layers (the barrier layers) and the metal layers on the substrate 300.

Please refer to FIG. 3C. A portion of the conductive material layer 310 is removed, so that an upper surface of the conductive material layer 310 is lower than an upper surface of the mask layer 304, whereby a select gate 310a is formed. The method of removing a portion of the conductive material layer 310 is, for instance, an etching back. The channel width underneath the select gate 310a can be determined by the depth of the removed device isolation structure or the depth of the notch of the active area. In the step of removing the portion of the conductive material layer 310 to form the select gate 310a, the select gate 310a is made to extrude the surface of the substrate 300 and a top of the select gate 310a is made to have a surface of a recession 312.

Please refer to FIG. 3D. The mask layer 304, the liner layer 302, and a portion of the gate dielectric layer 308 are removed after the select gate 310a is formed. A method of removing the mask layer 304, the liner layer 302, and a portion of the gate dielectric layer 308 is, for instance, a wet etching. Then, an inter gate dielectric layer 314 is formed on the substrate 300 and surface of select gate 310a. Material of the inter gate dielectric layer 314 is, for instance, silicon oxide. Methods of forming the inter gate dielectric layer 314 are, for instance, the thermal oxidation, the chemical vapor deposition, or the atomic layer deposition, etc.

A conductive material layer 316 is formed on the inter gate dielectric layer 314, wherein material of the conductive material layer 316 is, for instance, doped polysilicon. A method of forming the conductive material layer 316 is, for instance, performing an ion implantation step after using the chemical vapor deposition to form an undoped polysilicon layer; or, using the chemical vapor deposition by way of an in-situ dopant implantation.

Please refer to FIG. 3E. The conductive material layer 316 is patterned to form a floating gate 316a, wherein a portion of the floating gate 316a is disposed on the select gate 310a and fills the recession 312 at the top of the select gate 310a. In the step, the conductive material layer 316 is patterned to become block-shaped (as shown in FIG. 1A). A method of patterning the conductive material layer 316 is, for instance, the lithography-etching technique. In the invention, the floating gate 316a can be manufactured in the same process step with a gate of a transistor in a peripheral circuit area.

Next, the ion implantation step is performed, so as to form a doping region 320 (a source region) and a doping region 322 (a drain region) in the substrate 300 at both sides of the floating gate 316a and the select gate 310a. The doping region 322 (the drain region) is adjacent to a side of the select gate 310a. The doping region 320 (the source region) overlaps to a side of the floating gate 316a. The doping region 320 (the source region) and the doping region 322 (the drain region) are separated by the select gate 310a and the floating gate 316a and are opposed to each other. Then, a plug 324 for connecting to the bit line is formed in the doping region 322 (the drain region). The subsequent processes of completing the select gate flash memory are well known by those skilled in the art, thus are not reiterated herein.

In the above-mentioned embodiment, by disposing the select gate in the trench in the substrate, the size of the device can be reduced in the split gate flash memory and the manufacturing method thereof of the invention. Also, the channel length of the select gate can be controlled by the depth of the trench.

In the split gate flash memory and the manufacturing method thereof of the invention, since the trench is formed in the substrate, the channel region of the select gate is configured in the substrate along the sidewall of the trench (vertical channel region). Therefore, even the device dimension is reduced, the channel length is accurately controlled by controlling the depth of the trench. The problem of a leakage between the source region and the drain region after programming is prevented. Further, the integration of device can also increase.

In addition, in the split gate flash memory and the manufacturing method thereof of the invention, since the portion of the select gate is saddle-shaped and is across the active area or the portion of the select gate is slightly fin-shaped and extrudes the active area, the memory cell has the three dimensional channel path, which increases the channel width. According to the fact that the channel width underneath the select gate is increased, the size of the memory cell can be reduced, thereby increasing the level of integration of the device. Furthermore, the channel width underneath the select gate can be determined by the depth of the removed device isolation structure or the depth of the notch of the active area.

Moreover, in the split gate flash memory and the manufacturing method thereof of the invention, since the floating gate extrudes the select gate and the sharp corner is formed, a higher electric field can be produced at the corner. Accordingly, when the data erase operation is performed on the flash memory, the time required for the data erase operation can be shortened, and the voltage applied to the select gate can also be reduced.

It will be apparent to those skilled in the art that various modifications and variations can be made to the structure of the disclosed embodiments without departing from the scope or spirit of the invention. In view of the foregoing, it is intended that the disclosure cover modifications and variations of this specification provided they fall within the scope of the following claims and their equivalents.

What is claimed is:

1. A split gate flash memory, comprising:
a device isolation structure, disposed in a substrate to define an active area;
a first doping region and a second doping region, respectively disposed in the active area of the substrate;
a select gate, disposed in a trench of the substrate, wherein a side of the select gate is adjacent to the first doping region;
a gate dielectric layer, disposed between the select gate and the substrate;
a floating gate, disposed on the substrate, wherein a side of the floating gate overlaps to the second doping region and a portion of the floating gate is disposed on the select gate; and
an inter gate dielectric layer, disposed between the floating gate and the select gate and between the floating gate and the substrate.

2. The split gate flash memory as claimed in claim 1, wherein a surface of the device isolation structure in the trench is lower than a surface of the substrate, and a portion of the select gate is saddle-shaped and is across the active area.

3. The split gate flash memory as claimed in claim 1, wherein a notch is formed in the active area between the device isolation structures in the trench, and a portion of the select gate is fin-shaped and extrudes the active area.

4. The split gate flash memory as claimed in claim 1, wherein a portion of the floating gate extrudes the select gate and a corner where the floating gate extrudes the select gate has a sharp shape.

5. The split gate flash memory as claimed in claim 1, wherein a material of the select gate comprises metal or doped polysilicon.

6. The split gate flash memory as claimed in claim 1, wherein a material of the floating gate comprises doped polysilicon.

7. The split gate flash memory as claimed in claim 6, wherein a surface of the device isolation structure in the trench is lower than a surface of the substrate and a portion of the select gate is saddle-shaped and is across the active area.

8. The split gate flash memory as claimed in claim 6, wherein a notch is formed in the active area between the device isolation structures in the trench, and a portion of the select gate is fin-shaped and extrudes the active area.

9. The split gate flash memory as claimed in claim 6, wherein a portion of the floating gate extrudes the select gate and a corner where the floating gate extrudes the select gate has a sharp shape.

10. A manufacturing method of the split gate flash memory, comprising:
forming a device isolation structure in a substrate to define an active area;
forming a patterned mask layer on the substrate;
removing a portion of the device isolation structure and the substrate by using the patterned mask layer as a mask to form a trench in the substrate;
forming a gate dielectric layer in the trench;
forming a select gate in the trench, wherein the select gate fills the trench;
removing the patterned mask layer;
forming an inter gate dielectric layer on the substrate;
forming a floating gate on the substrate, wherein a portion of the floating gate is disposed on the select gate; and
forming a first doping region and a second doping region in the substrate on both sides of the floating gate and the select gate, wherein the first doping region is adjacent to a side of the select gate and the second doping region overlaps to a side of the floating gate.

11. The manufacturing method of the split gate flash memory as claimed in claim 10, wherein the step of removing a portion of the device isolation structure and the substrate by using the patterned mask layer as the mask to form the trench in the substrate comprises:
removing a portion of the device isolation structure to form a notch in the device isolation structure.

12. The manufacturing method of the split gate flash memory as claimed in claim 10, wherein the step of removing a portion of the device isolation structure and the substrate using the patterned mask layer as the mask to form the trench in the substrate comprises:
removing a portion of the substrate to form a notch between the device isolation structures.

13. The manufacturing method of the split gate flash memory as claimed in claim 10, wherein the step of forming the select gate in the trench comprises:
forming a conductive material layer on the substrate to fill the trench; and
removing a portion of the conductive material layer to form a recess surface on the conductive material layer.

14. The manufacturing method of the split gate flash memory as claimed in claim 10, wherein the step of forming the gate dielectric layer in the trench comprises preforming a thermal oxidation.

15. The manufacturing method of the split gate flash memory as claimed in claim 10, wherein the step of forming the floating gate on the substrate comprises:
forming a conductive material layer on the substrate; and
patterning the conductive material layer.
